(19) United States
(12) Patent Application Publication
(10) Pub. No.: US 2026/0034909 A1
(43) Pub. Date: Feb. 5, 2026

(54) WIRELESS POWER TRANSFER SYSTEM, TEST METHOD FOR POWER TRANSMISSION APPARATUS, POWER TRANSMISSION APPARATUS, AND POWER RECEPTION APPARATUS

(71) Applicant: DENSO CORPORATION, Kariya-city (JP)

(72) Inventors: Kazuyoshi OBAYASHI, Kariya-city (JP); Nobuhisa YAMAGUCHI, Kariya-city (JP); Keisuke TANI, Kariya-city (JP); Masaki KANESAKI, Kariya-city (JP)

(73) Assignee: DENSO CORPORATION, Kariya-city (JP)

(21) Appl. No.: 19/352,734

(22) Filed: Oct. 8, 2025

Related U.S. Application Data
(63) Continuation of application No. PCT/JP2024/014348, filed on Apr. 9, 2024.

(30) Foreign Application Priority Data
Apr. 12, 2023 (JP) 2023-064898

(51) Int. Cl. B60L 53/60; B60L 53/122; G01R 22/06; G01R 31/00

(52) U.S. Cl. CPC B60L 53/60; B60L 53/122; G01R 22/061; G01R 31/002

(57) ABSTRACT

In a wireless power transfer system, a performance of a power transmission apparatus is to be tested by the wireless power transfer system. The power transmission apparatus is configured to wirelessly transmit power, and a power reception apparatus is configured to receive the power. The power transmission apparatus includes a power transmission coil for wireless transmission of the power, a power supply unit configured to output, to the power transmission coil, the power to be used for the wireless transmission, and a first controller configured to control the power supply unit. The power reception apparatus includes a power reception coil for receiving the power transmitted from the power transmission apparatus. The first controller is configured to store information indicative of control modes that include a cycle switching mode in which the first controller changes the output of the power supply unit with a predetermined first cycle.

### CROSS-REFERENCE TO RELATED APPLICATION

This present application is a bypass continuation application of currently pending international application No. PCT/JP2024/014348 filed on Apr. 9, 2024, designating the United States of America, the entire disclosure of which is incorporated herein by reference, the international application being based on and claiming the benefit of priority from Japanese Patent Application No. 2023-064898 filed on Apr. 12, 2023, the disclosure of which is incorporated herein by reference.

### TECHNICAL FIELD

The present disclosure relates to wireless power transfer systems, test methods for a power transmission apparatus, power transmission apparatuses, and power reception apparatuses.

### BACKGROUND

As described in Non-Patent Literature 1, which is “Wireless Power Transfer for Light-Duty Plug-in/Electric Vehicles and Alignment Methodology”, SAE J2954, SAE International, October 2020, Electromagnetic Compatibility (EMC) tests are performed under continuous power transfer, both in a first mode where the transmitting and receiving coils are aligned to face each other and in a second mode where they are misaligned.

Wireless power transfer is performed for a running vehicle or a stationary vehicle. Wireless power transfer to a running vehicle is carried out in a situation where the vehicle is running on a road in or on which multiple power transmission coils of a wireless power transfer apparatus are mounted along the road. That is, wireless power transfer sequentially switches energization of the multiple power transmission coils while the vehicle is running on the road. In such a wireless power transfer apparatus, the switching of energization of the multiple power transmission coils may cause variations in the outputs of the multiple power transmission coils, resulting in the occurrence of noise depending on the energization switching cycle of the multiple power transmission coils.

### SUMMARY

EMC tests for stationary wireless power transfer to a stationary vehicle are generally performed with a distance of 10 m between the measuring antenna and the equipment under test (EUT), i.e., requiring a 10-m method anechoic chamber. In EMC tests for dynamic power transfer, switching of energization of multiple power transmission coils is required while a power reception coil is moving relative to the power transmission coils to simulate vehicle travel. For this reason, EMC tests for dynamic wireless power transfer are carried out in an anechoic chamber wider than that for EMC tests for a stationary vehicle.

Accordingly, EMC tests for dynamic wireless power transfer may be more expensive than those for stationary wireless power transfer, resulting in a difficulty in carrying out EMC tests for dynamic wireless power transfer.

Additionally, the energization switching operations among the power transmission coils included in the wireless power transfer apparatus may be changed depending on change in the apparatus and/or environments over time. Unfortunately, if, for example, the power transmission coils are embedded in the ground, it may be difficult to easily test coil-energization switching operation. For this reason, there has been a need for technology capable of easily testing in a simulated manner the coil-energization switching operation.

The present disclosure can be achieved as an exemplary aspects described hereinafter.

A first aspect of the present disclosure provides a wireless power transfer system. The wireless power transfer system includes a power transmission apparatus whose performance is to be tested by the wireless power transfer system. The power transmission apparatus being configured to wirelessly transmit power. The wireless power transfer system includes a power reception apparatus configured to receive the power. The power transmission apparatus includes a power transmission coil for wireless transmission of the power, a power supply unit configured to output, to the power transmission coil, the power to be used for the wireless transmission, and a first controller configured to control the power supply unit. The power reception apparatus includes a power reception coil for receiving the power transmitted from the power transmission apparatus. The first controller is configured to store information indicative of a plurality of control modes for controlling the output of the power supply. The control modes include a cycle switching mode in which the first controller changes the output of the power supply unit with a predetermined first cycle.

The power transmission apparatus according to the first aspect is configured to output, in the cycle switching mode, power to be used for power transfer with the predetermined first cycle.

For example, when the power reception apparatus is an electric vehicle, the electric vehicle receives power while traveling with energization switching among power transmission coils (i.e., the coils are sequentially energized). Accordingly, the power transmission apparatus outputs power in accordance with the coil switching. The coil switching occurs with a cycle based on the vehicle speed. Therefore, setting the first cycle of the cycle switching mode to the cycle based on the vehicle speed in the wireless power transfer system enables intermittent control of the output of the power transmission apparats, making it possible to test the performance of the power transmission apparatus under simulated coil switching without running the electric vehicle. Because the wireless power transfer system is configured to simulate the energization switching operation of the power transmission coils to thereby test the energization switching operation in a stopped state of the electric vehicle, making it possible to test the performance of the power transmission apparatus more readily than when testing it in a moving state of the electric vehicle.

A second aspect of the present disclosure provides a test method. The test method includes
(I) Preparing a power transmission apparatus whose performance is to be tested by the test method, the power transmission apparatus being configured to wirelessly transmit power,
   the power transmission apparatus including:
      a power transmission coil for wireless transmission of the power, the power transmission coil having a predetermined power-suppliable section of the wireless transmission of the power;
      a power supply unit configured to output, to the power transmission coil, the power to be used for the wireless transmission; and
      a first controller configured to control the power supply unit;
(II) Preparing a power reception apparatus including a power coil for receiving the power transmitted from the power transmission apparatus;
(III) Preparing a test device for measuring the performance of the power transmission apparatus;
(IV) Arranging the power transmission coil and the power reception coil at predetermined relative positions such that the power reception coil is located within the power-suppliable section of the power transmission coil and does not face the power transmission coil; and
(V) Controlling the power supply unit to output the power from the power supply unit at a predetermined cycle.

The test method according to the second aspect performs the performance test of the power transmission apparatus while changing the relative position of the power reception coil to the power transmission coil. This makes it possible to carry out the performance test of the power transmission apparatus while simulating transition of electromagnetic coupling between the power reception coil and the power transmission coil.

For example, when the power reception apparatus is installed in an electric vehicle during actual use of the power transmission apparatus, the power reception coil receives power wirelessly while energization is sequentially switched among power transmission coils. At that time, because the relative position of the power reception coil to an energized power transmission coil is changed with movement of the electric vehicle, electromagnetic coupling between the power reception coil and the energized power transmission coil is changed with movement of the electric vehicle.

From this viewpoint, the test method according to the second aspect carries out the performance test of the power transmission apparatus while changing, in accordance with change of electromagnetic coupling between the power reception coil and the power transmission coil, the relative position of the power reception coil to the power transmission coil. This therefore makes it possible to carry out the performance test of the power transmission apparatus while the electromagnetic conditions around the power transmission apparatus are close to those around the actually used power transmission apparatus.

Additionally, the test method according to the second aspect outputs, from the power supply unit, power at a predetermined cycle that matches the energization switching cycle of the power transmission coils during actual use of the power transmission apparatus. This therefore makes it possible to perform, with the power reception coil stopped, the performance test of the power transmission apparatus while simulating energization switching of the power transmission coils.

A third aspect of the present disclosure provides a power transmission apparatus according to a ninth feature is in a wireless power transfer system for testing a wireless power-transfer performance of the power transmission apparatus. The wireless power transfer system includes a power reception apparatus including a power reception coil so that the power reception apparatus receives, through the power reception coil, power wirelessly transmitted from the power transmission apparatus. The power transmission apparatus includes a power transmission coil for wireless transmission of the power, a power supply unit configured to output, to the power transmission coil, the power to be used for the wireless transmission, and a first controller configured to control the power supply unit. The first controller is configured to store information indicative of a plurality of control modes for controlling the output of the power supply. The control modes include a cycle switching mode in which the first controller changes the output of the power supply unit with a predetermined first cycle.

The power transmission apparatus according to the third aspect is configured to output, in the cycle switching mode, power to be used for power transfer with the predetermined first cycle.

For example, when the power reception apparatus is an electric vehicle, the electric vehicle receives power while traveling with energization switching among power transmission coils (i.e., the coils are sequentially energized). Accordingly, the power transmission apparatus outputs power in accordance with the coil switching. The coil switching occurs with a cycle based on the vehicle speed. Therefore, setting the first cycle of the cycle switching mode to the cycle based on the vehicle speed in the wireless power transfer system enables intermittent control of the output of the power transmission apparats, making it possible to test the performance of the power transmission apparatus under simulated coil switching without running the electric vehicle. Because the wireless power transfer system is configured to simulate the energization switching operation of the power transmission coils to thereby test the energization switching operation in a stopped state of the electric vehicle, making it possible to test the performance of the power transmission apparatus more readily than when testing it in a moving state of the electric vehicle.

A fourth feature provides a power reception apparatus according to a tenth feature, including a power receiving coil, is for use with a wireless power transmission apparatus that includes a power transmission coil for wireless transmission of power, a power supply unit configured to output, to the power transmission coil, the power to be used for the wireless transmission, and a first controller configured to control an output of the power supply unit in a plurality of modes including a cycle switching mode in which the transmission output is varied with a predetermined first period. The power reception coil is configured to receive, through the power reception coil, the power wirelessly transmitted from the power transmission apparatus.

The power transmission apparatus according to the fourth aspect is configured to output, in the cycle switching mode, power to be used for power transfer with the predetermined first cycle.

For example, when the power reception apparatus is an electric vehicle, the electric vehicle receives power while traveling with energization switching among power transmission coils (i.e., the coils are sequentially energized). Accordingly, the power transmission apparatus outputs power in accordance with the coil switching. The coil switching occurs with a cycle based on the vehicle speed. Therefore, setting the first cycle of the cycle switching mode to the cycle based on the vehicle speed in the wireless power transfer system enables intermittent control of the output of the power transmission apparats, making it possible to test the performance of the power transmission apparatus under simulated coil switching without running the electric vehicle. Because the wireless power transfer system is configured to simulate the energization switching operation of the power transmission coils to thereby test the energization switching operation in a stopped state of the electric vehicle, making it possible to test the performance of the power transmission apparatus more readily than when testing it in a moving state of the electric vehicle.

### BRIEF DESCRIPTION OF THE DRAWINGS

Other aspects of the present disclosure will become apparent from the following description of embodiments with reference to the accompanying drawings in which:

FIG. 1 is a block diagram illustrating a schematic configuration of a wireless power transfer system according to the first embodiment;

FIG. 2 is a block diagram illustrating a functional configuration of a first controller according to the first embodiment;

FIG. 3 is a block diagram illustrating energization switching among power transmission coils;

FIG. 4 is a graph illustrating the waveform of an output current from a power supply unit in a normal mode;

FIG. 5 is a graph illustrating the waveform of the output current from the power supply unit in a cycle switching mode;

FIG. 6 is a flowchart illustrating a test procedure carried out by the wireless power transfer system;

FIG. 7 is block diagram illustrating a functional configuration of a first controller according to the second embodiment;

FIG. 8 is block diagram illustrating a functional configuration of a first controller according to the third embodiment;

FIG. 9 is a graph illustrating the waveform of the output current from the power supply unit in a variable efficiency mode;

FIG. 10 is a block diagram illustrating a schematic configuration of a wireless power transfer system according to the fourth embodiment; and

FIG. 11 is a block diagram illustrating relative positions between a power transmission coil and a power reception coil.

### DETAILED DESCRIPTION OF EMBODIMENTS

### First Embodiment

### Configuration of Wireless Power Transfer System

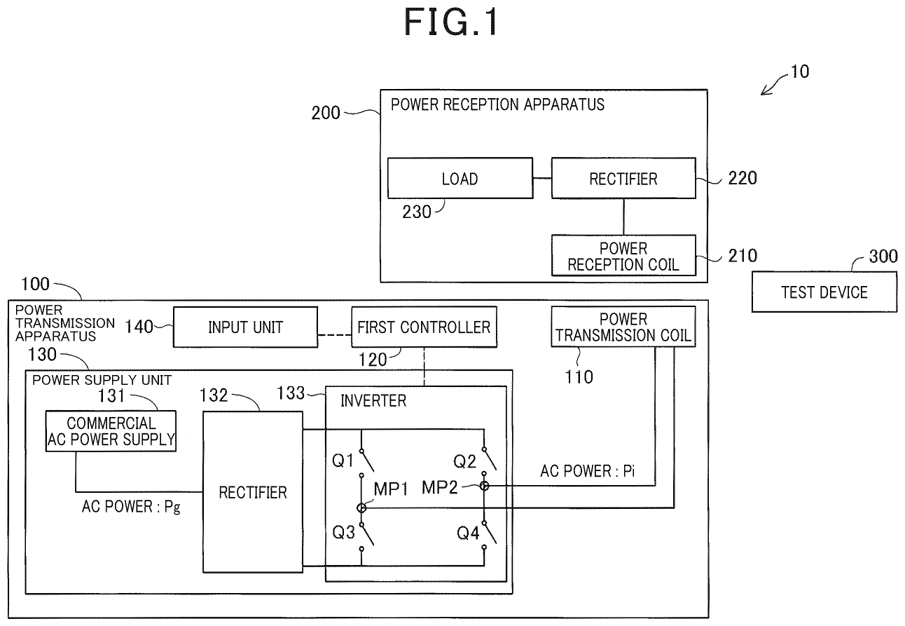

A wireless power transfer system 10 illustrated in FIG. 1 aims to test the performance of a power transmission apparatus 100 for wireless power transfer. Specifically, the wireless power transfer system 10 is configured to test the performance of the power transmission apparatus 100 that performs a coil-energization switching operation. For example, the performance test of the power transmission apparatus 100 includes EMC tests, power supply efficiency tests for wireless power transfer, and other tests. The wireless power transfer system 10 includes the power transmission apparatus 100, a power reception apparatus 200 including a power reception coil 210, and a test device 300.

The power transmission apparatus 100 is configured to perform wireless power transfer to the power reception apparatus 200. Specifically, the power transmission apparatus 100 is configured to wirelessly supply power through a power transmission coil 110 to the power reception coil 210 of the power reception apparatus 200. The power transmission coil 110 and the power reception coil 210 wirelessly transfer power through magnetic resonance coupling therebetween. For example, the power transmission apparatus 100 is configured as a charging stand for wireless power transfer from the power transmission coil 110 to the power reception coil 210 included in an electric vehicle EV.

The power transmission apparatus 100 includes the power transmission coil 110, a first controller 120, a power supply unit 130, and an input unit 140.

The power supply unit 130 is configured to output, to the power transmission coil 110, power to be used for power transfer. The power supply unit 130 includes a commercial alternating-current (AC) power supply 131, a rectifier 132, and an inverter 133. The commercial AC power supply 131 is electrically connected to the rectifier 132, and the rectifier 132 is electrically connected to the inverter 133. The commercial AC power supply 131 is configured to output, to the rectifier 132, AC power Pg having a predetermined commercial frequency. The rectifier 132 is configured to convert the AC power Pg having the commercial frequency into direct-current (DC) power.

The inverter 133 is configured to convert the DC power output from the rectifier 132 into AC power Pi based on a frequency required for power transfer through the power transmission coil 110. Specifically, the inverter 133 is configured to convert the DC power output from the rectifier 132 into AC power Pi based on a resonant frequency between the power transmission coil 110 and the power reception coil 210, which is described later. The inverter 133 is, for example, a full-bridge inverter comprised of, for example, four switching devices Q1, Q2, Q3, and Q4 connected in a full-bridge configuration. For the sake of understanding of input/output to/from the inverter 133, two lines extending from the rectifier 132 to the inverter 133 are illustrated as input/output lines in FIG. 1, and two lines extending from the power transmission coil 110 to the inverter 133 are illustrated as input/output lines in FIG. 1.

The first controller 120 is configured to supply a switch control signal to each of the switching devices Q1, Q2, Q3, and Q4 to accordingly control the corresponding one of the switching devices Q1, Q2, Q3, and Q4 to be in an on state or an off state. The power transmission coil 110 is connected between a first connection point between the switching devices Q1 and Q4 and a second connection point between the switching devices Q2 and Q3.

Controlling the pair of switching devices Q1 and Q4 and the pair of switching devices Q2 and Q3 to be alternately in the on state enables the AC power Pi for power transfer to be supplied to the power transmission coil 110. The AC power Pi has a frequency Fp, which will be referred to as a power-transfer frequency Fp. That is, the power-transfer frequency Fp denotes an operation frequency for the switching devices Q1 to Q4 for generation of the AC power Pi. The power-transfer frequency Fp according to the first embodiment is set to be substantially identical to the resonant frequency. The output of the inverter 133 and the output of the power supply unit 130 are treated as having the same meaning in the first embodiment.

The power transmission coil 110 is configured to perform wireless power transfer to the power reception circuit 200. Specifically, the power transmission coil 110 constitutes a resonance circuit including a capacitor. More specifically, the power transmission coil 110 serves as a resonance circuit designed to have the resonant frequency of 85 kHz when being magnetically coupled with the power reception coil 210.

When being connected to the inverter 133, the power transmission coil 110 is configured to receive the AC power Pi with the frequency of 85 kHz, and generate an AC magnetic field therearound based on the received AC power Pi. The power reception coil 210 is configured to resonate with the AC magnetic field generated therearound to accordingly receive the AC power Pi. How the power transmission coil 110 is arranged will be described later. A noise-suppression filter may be interposed between the inverter 133 and the power transmission coil 110.

The resonance circuit constituted by the power transmission coil 110 is a series resonance circuit. When the inverter 133 for example outputs a square-wave AC voltage with 85 kHz, the power transmission coil 110 serves as the resonance circuit to output a sinusoidal AC voltage with 85 kHz. For this reason, in at least one of the following drawings, an output current of the power supply unit 130, which serves as power for wireless transfer, is illustrated as a sinusoidal-wave current. The resonance circuit constituted by the power transmission coil 110 may be changed from the series resonance circuit to another resonance circuit, such as a parallel resonance circuit.

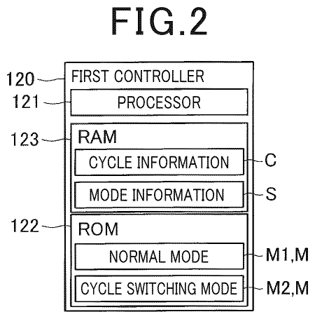

The first controller 120 illustrated in FIG. 2 is configured to control overall operations of the power transmission apparatus 100. Specifically, the first controller 120 is configured to control the switching devices Q1 to Q4 of the inverter 133 to accordingly control how the power transmission apparatus 100 performs wireless power supply to the power reception apparatus 200.

The first controller 120 includes a processor 121, a read-only memory (ROM) 122, and a random-access memory (RAM) 123. The ROM 122 is a read-only semiconductor memory, and stores various programs including control programs for control of the inverter 133.

That is, the ROM 122 stores information indicative of a plurality of control modes M for controlling the power supply unit 130, which include a normal mode M1 and a cycle switching mode M2. Each of the normal mode M1 and the cycle switching mode M2 will be described later.

The RAM 123 is a semiconductor memory serving as a main memory, and the power transmission apparatus 100 may include auxiliary storage devices such as a hard-disk drive or a solid-state drive.

The RAM 123 is capable of storing information required to control the power supply unit 130. Specifically, the RAM 123 stores cycle information C serving as a parameter related to the control modes M for the power supply unit 130, and mode information S for selecting one of the control modes M. The cycle information C and the mode information S will be described later.

The processor 121 is configured to execute the various programs stored in the ROM 122 to accordingly implement various functions. The processor 121 is additionally configured to store, in the RAM 123, information required to operations thereof. The functions implemented by the processor 121 will be described later.

The first controller 121 is connected to each of the switching devices Q1 to Q4 through a drive circuit. The drive circuit is configured to output, to each of the switching devices Q1 to Q4, a corresponding one of the switching control signals in accordance with control signals supplied from the first controller 121. Each of the switching control signals output to the corresponding one of the switching devices Q1 to Q4 drives the corresponding one of the switching devices Q1 to Q4.

The input unit 140 is configured to input, to the first controller 120, information for controlling the power supply unit 130. The input unit 140 is configured to input, to the first controller 120, at least cycle information C when externally operated. The input unit 140 includes switches. The switches are each electrically connected to the first controller 120. The first controller 120 stores candidate values determined for the cycle information C and candidate values determined for the mode information S.

When the switches are selectively operated, the switches transmit, to the first controller 120, selection signals based on the selective operations, and the first controller 120 selects, based on the selection signals, one of the candidate values determined for the cycle information C and one of the candidate values determined for the mode information S to accordingly update (i) the cycle information C to the selected candidate value and (ii) the mode information S to the selected candidate value.

The test device 300 is configured to test the performance of the power transmission apparatus 100. The test device 300 serves as, for example, an EMC test device and/or a power meter. The test device 300, when serving as an EMC test device, is configured to test EMC of the power transmission apparatus 100 when the power transmission apparatus 100 performs a coil-energization switching operation. The test device 300, when serving as a power meter, is connected to the power supply unit 130 and a load 230, and is configured to measure the power transfer efficiency of wireless power transfer between the power supply unit 130 and the load 230.

The power reception apparatus 200 is configured to receive power. Specifically, the power reception apparatus 200 is a reference test receiver for testing the power transmission apparatus 100. The power reception apparatus 200 includes the power reception coil 210, a rectifier 220, and the load 230.

The power reception coil 210 is configured to perform wireless power reception. Specifically, the power reception coil 210 constitutes a resonance circuit including a capacitor. More specifically, the power reception coil 210 serves as a resonance circuit designed to have the resonant frequency of 85 kHz when being magnetically coupled with the power transmission coil 110.

The power reception coil 210 is configured to receive the AC magnetic field generated by the power transmission coil 110, and is connected to the rectifier 220. The power reception coil 210 is configured to resonate with the AC magnetic field generated therearound, so that induced electromotive force is generated as AC power therethrough. Then, the AC power is received by the rectifier 220.

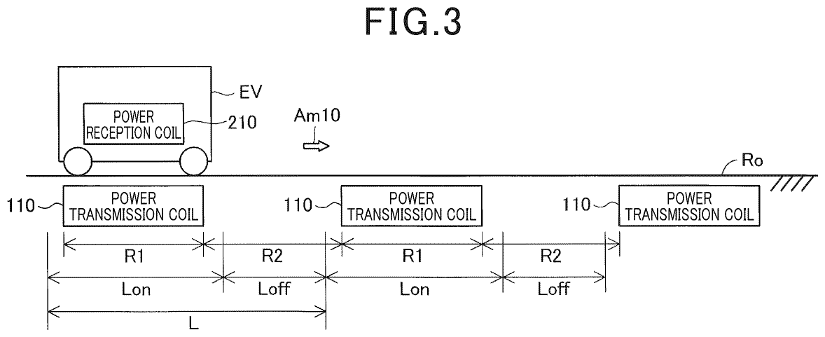

The power reception coil 210 is arranged to face the power transmission coil 110. That is, the power reception coil 210 is located within a predetermined power-suppliable section Lon with respect to the power transmission coil 110. By way of illustration for explaining the power-suppliable section, as shown in FIG. 3, the following describes an example where an electric vehicle EV equipped with the power reception coil 210 travels on a road Ro on or in which a plurality of power transmission coils 110 are laid. In the example illustrated in FIG. 3, the plurality of power transmission coils 110 are arranged at equal intervals along the traveling direction, which is indicated by arrow Am10, of the electric vehicle EV.

On the road Ro on or in which the plurality of power transmission coils 110 are installed, there exist a pair of power-suppliable section and a power-unsuppliable section defined for each power transmission coil 110 with respect to the power receiving coil 210. Whether power can be supplied from each power transmission coil 110 to the power reception coil 210 is determined based on the electromagnetic coupling state between the power transmission coil 110 and the power receiving coil 210. Let us assume that the power-suppliable section has a length Lon in the direction parallel to the traveling direction Am10, and the power-unsuppliable section has a length Loff in the direction parallel to the traveling direction Am10. In this assumption, FIG. 3 illustrates that the power reception coil 210 is located within the power-suppliable section Lon of a power transmission coil 110. Hereinafer, the sum of length Lon and length Loff will be referred to as a pitch L, which denotes an interval of wireless power transfer while the electric vehicle EV is traveling. In this specification, L also denotes a coil pitch, defined as L=Lon+Loff.

Note that the length Lon is different from a length R1 corresponding to the longitudinal length of the power transmission coil 110. Specifically, assuming that the length of an interval between adjacent power transmission coils 110 in the traveling direction Am10 where no power transmission coil 110 is present is referred to as R2, the length R1 and the length R2 satisfy the first relationship of R1<Lon and the second relationship of R2>Loff.

These relationships can be satisfied for each of the power transmission coils arranged at equal intervals. Although the dimensional relationships are shown based on FIG. 3, the dimensions of the coils 110 and 210 may vary depending on, for example, the shape of each coil. For example, the dimensions of the coils 110 and 210 may be determined such that the power receiving coil 210 may be longer than the power transmission coil 110 or power may be transmitted from selected coils in the power transmission coils 110 to the power reception coil 210.

When the power reception coil 210 is located within the power-suppliable section Lon of a power transmission coil 110, power is received because the impedance of the resonant circuit of the power reception circuit 210 decreases due to magnetic-field resonant coupling. At this time, the power supply unit 130 is in an output ON state in which the power supply unit 130 outputs a current for the AC power Pi.

In contrast, when the power receiving coil 210 is located within the power-unsuppliable section Loff of a power transmission coil 110, power cannot be received because the impedance of the resonant circuit of the power reception circuit 210 is high. At this time, the power supply unit 130 is in an output OFF state in which the power supply unit 130 outputs no current. A period of the output ON state of the power supply unit 130 will be referred to as an output ON period Ton, and a period of the output OFF state of the power supply unit 130 will be referred to as an output OFF period Toff, which will be described later. The output ON period Ton will also be referred to as a first period Ton, and the output OFF period Toff will also be referred to as a second period Toff.

The rectifier 220 illustrated in FIG. 1 is configured to receive AC power from the power reception coil 210 and convert the AC power into DC power. The rectifier 220, which is connected to both the power reception coil 210 and the load 230, is configured to output the DC power to the load 230.

The load 230 is an apparatus configured to receive the DC power and use the received DC power. Specifically, the load 230 is an electronic load. Because the power receiving apparatus 200 serves as a reference receiver for EMC testing, the load 230 simulates a load, such as a battery for an electric vehicle EV, of a power receiving apparatus that actually receives power from the power transmission apparatus 100.

### Normal Mode

The first controller 120 is configured to store therein the control modes M for controlling the output of the power supply unit 130. Specifically, the first controller 120 is configured to store therein the normal mode M1 and the cycle switching mode M2 as the control modes M. Each control mode M denotes a corresponding procedure of controlling the switching devices Q1 to Q4 of the inverter 133. The first controller 120 is configured to receive, from the input unit 140, the mode information S denoting selection of one of the control modes M. Then, the first controller 120 is configured to select, from the control modes M, i.e., the normal mode M1 and the cycle switching mode M2, one of the normal mode M1 and the cycle switching mode M2 in accordance with the mode information S.

The normal mode M1 is a control mode for the power supply unit 130 in which the output of the power supply unit 130 is continuously supplied without being varied in an intermittent cycle. Specifically, in the normal mode M1, the switching devices Q1 to Q4 are continuously driven at the power-transfer frequency Fp determined by the resonant frequency, e.g., 85 kHz, of the power transmission/reception coils 110 and 210. That is, the normal mode M1 does not denote a control mode of the switching devices Q1 to Q4 used for the performance test carried out by the test device 300, but denotes a control mode of the switching devices Q1 to Q4, which determines the output of the power supply unit 130 of the power transmission apparatus 100 that is actually being used.

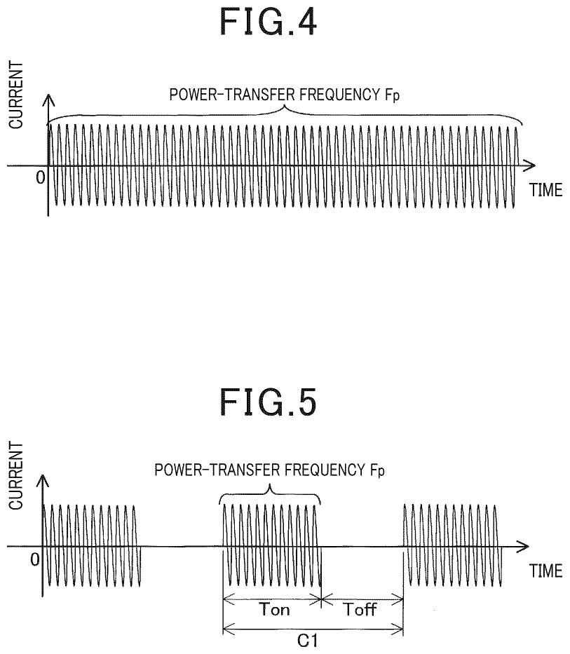

For example, in the normal mode M1, the switching devices Q1 to Q4 of inverter 133 are controlled to switch at a frequency equal to the resonant frequency of the power transmission/reception coils 110 and 210, for example, 85 kHz. As shown in FIG. 4, an AC current at 85 kHz is output from the inverter 133 while the inverter 133 operates in the normal mode M1. Note that FIG. 4 illustrates the waveform of the AC current in a steady state while the inverter 133 operates in the normal mode M1.

### Cycle Switching Mode

The cycle switching mode M2 is a control mode for the power supply unit 130 in which the output of the power supply unit 130 is changed with a predetermined first cycle. Specifically, in the cycle switching mode M2, the output of the power supply unit 130 is varied with a cycle corresponding to the cycle of energization switching among the power transmission coils 110 that occurs during actual use of the power transmission apparatus 100.

The cycle of energization switching among the power transmission coils 110 that occurs during actual use of the power transmission apparatus 100 occurs, as illustrated in FIG. 3, when the power reception coil 210 of the electric vehicle EV traveling along the road Ro receives power from the power transmission coils 110 mounted on/in the road Ro. Each time the power reception coil 210 passes through any power-unsuppliable section of length Loff in the traveling direction Am10, the power reception coil 210 subsequently enters the power-suppliable section adjacent to that power-unsuppliable section. For this reason, the power reception coil 210 receives power wirelessly while energization is sequentially switched among the power transmission coils 110. That is, the cycle of switching energization among the power transmission coils 110 is a cycle with which one of the power transmission coils 110 as a power transfer target to the power reception coil 210 is switched to an adjacent one of the power transmission coils 110. The energization switching cycle of the power transmission coils 110 is the interval between successive changes from one transmission coil to the next coil that supplies power to the power reception coil 210. The energization switching cycle of the power transmission coils 110 will be referred to as a first cycle C1.

As described above, the state of the output current from the power supply unit 130 changes depending on whether the power reception coil 210 is located in the power-suppliable section or the power-unsuppliable section. Specifically, as shown in FIG. 5, the power supply unit 130 outputs current intermittently, with the output ON period (Ton) during which current is supplied and the output OFF period (Toff) during which no current is supplied. That is, the first cycle C1 is defined as a total time of the output ON period Ton during which the output of the power supply unit 130 is executed and the output OFF period Toff during which the output of the power supply unit 130 is stopped. During the output ON period Ton of each first cycle C1, the power reception coil 210 is located within a power-suppliable section having the length Lon, and during the output OFF period Toff of each first cycle C1, the power reception coil 210 is located within a power-unsuppliable section having the length Loff.

For this reason, the first cycle C1, i.e., the energization switching cycle of the power transmission coils 110, can be determined based on the traveling speed of the electric vehicle V and the pitch L between adjacent power transmission coils 110. Specifically, the first cycle C1 can be calculated in accordance with the following formula C1=L/V. For example, assuming that the traveling speed of the electric vehicle EV is 100 km/h and the pitch L between adjacent power transmission coils 110 is 1 m, the first cycle C1 can be calculated as 0.036 seconds. The frequency corresponding to the first cycle C1 is approximately 27 Hz.

The ratio of the output ON period Ton to the first cycle C1, which will be referred to as a duty ratio Don, is identical to the ratio of the length Lon of the power-suppliable section to the pitch L of adjacent power transmission coils 110. That is, the duty ratio Don can be calculated in accordance with the following formula Don=Lon/(Lon+Loff). This therefore enables the output ON period Ton can be calculated in accordance with the following formula Ton=Don×C1. The output off period Toff can be calculated in accordance with the following formula Toff=C1−Ton.

The first controller 120 is configured to control the inverter 133 in the cycle switching mode M2 to generate the current changing intermittently. Specifically, in the cycle switching mode M2, the first controller 120 turns off all the switching devices Q1 to Q4 in the output OFF period Toff. Additionally, in the cycle switching mode M2, the first controller 120 alternately switches the switching-device pair (Q1, Q4) and the switching-device pair (Q2, Q3) on and off at the power-transfer frequency Fp determined by the resonance frequency of the power transmission coil 110 and the power reception coil 210 (i.e., while one pair is ON, the other is OFF). That is, the first controller 120 is configured to stop output of the inverter 133 for the output OFF period Toff in each first cycle C1 that is longer than the cycle of the power-transfer frequency Fp.

Note that dead time during which all the switching devices Q1 to Q4 are turned off is ensured between turn-on of the switching-device pair (Q1, Q4) and turn-on of the switching-device pair (Q2, Q3) in each first cycle C1 to prevent the occurrence of a shoot-through current; the dead time is different from the output OFF period Toff.

The first cycle C1, the output ON period Ton, and the output OFF period Toff used in the cycle switching mode M2 and included in the cycle information C are determined based on the above conditions of the power transmission apparatus 100 that is actually used. The cycle information C is set based on operations of the input unit 140.

Accordingly, the first controller 120 is configured to control the inverter 133 based on the first cycle C1 including the output OFF period Toff to thereby control output of the power supply unit 130, making it possible to simulate the energization switching operation among the power transmission coils 110. For the sake of understanding of the technology, FIG. 5 illustrates the waveform of the current during each of the output ON period Ton and the output OFF period Toff in a steady state.

### Test Method

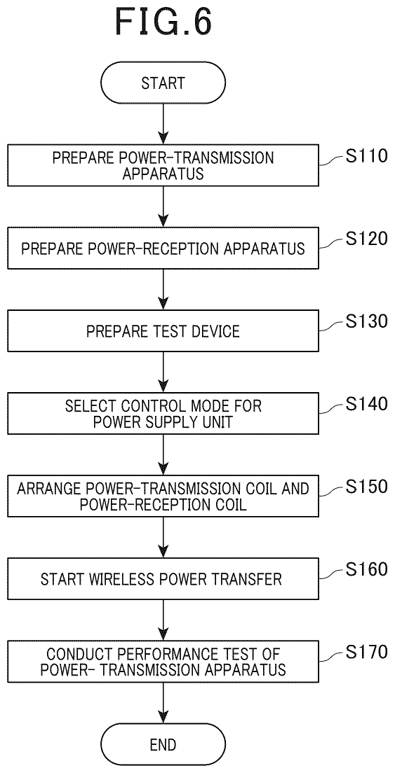

FIG. 6 is a flowchart illustrating a test procedure conducted with the contactless power transfer system 10 to evaluate the performance of the power transmission apparatus 100.

A test operator prepares the power transmission apparatus 100 for wireless power transfer to the power reception apparatus 200 in step S110 illustrated in FIG. 6. Specifically, the test operator prepares the power transmission apparatus 100 as its test target, which includes the power transmission coil 110 for power transfer, the power supply unit 130 for outputting, to the power transmission coil 110, power to be used for power transfer, and the first controller 120 for controlling overall operations of the power transmission apparatus 100.

Next, the test operator prepares the power reception apparatus 200 equipped with the power reception coil 210 for power reception in step S120 of FIG. 6. Specifically, the test operator prepares the power reception apparatus 200 including the power reception coil 210, the rectifier 220, and the load 230.

Following the step S120, the test operator prepares the test device 300 for measuring the performance of the power transmission apparatus 100 in step S130. Specifically, when performing the EMC test of the power transmission apparatus 100, the test operator prepares to set up an EMC measurement antenna and to install the power transmitting apparatus 100 and the power receiving apparatus 200 in an anechoic chamber. For measurement of wireless power transfer efficiency, the test operator prepares to connect respective power meters to the power transmission apparatus 100 and the power reception apparatus 200.

Following the step S130, when the test operator operates the input unit 140 to input the mode information S indicating the cycle switching mode M2, the first controller 120 sets the control mode M of the power supply unit 130 to the cycle switching mode M2 in step S140 of FIG. 6. In step S140 of FIG. 6, when the test operator operates the input unit 140 to input the cycle information C, the first controller 120 recognizes the cycle information C.

After the control mode M is set to the cycle switching mode M2, the relative position between the power transmission coil 110 and the power reception coil 210 is determined in step S150, so that the power reception coil 210 is located within the power-suppliable section of the power transmission coil 110.

Next, the test operator instructs the first controller 120 to control output of the power supply unit 130 in accordance with the first cycle C1 previously determined based on the cycle information C in step S160. That is, the test operator instructs the first controller 120 to control output of the power supply unit 130 in accordance with the first cycle C1 to accordingly perform wireless power transfer from the power transmission coil 110 and the power reception coil 210.

Following the step S160, the test operator conducts the performance test of the power transmission apparatus 110 in step S170. For example, the test operator instructs the test device 300 to perform EMC tests and/or measure the power transfer efficiency of the wireless power transfer.

The power transmission apparatus 100 according to the first embodiment is configured to output, in the cycle switching mode M2, power with the predetermined first cycle C1.

For example, when the power reception apparatus 200 is an electric vehicle EV, the electric vehicle EV receives power while traveling with energization switching among the power transmission coils 110 (i.e., the coils are sequentially energized). Accordingly, the power transmission apparatus 100 outputs power in accordance with the coil switching. The coil switching occurs with a cycle based on the vehicle speed V. Therefore, setting the first cycle C1 of the cycle switching mode M2 to the cycle based on the vehicle speed V in the wireless power transfer system 10 enables intermittent control of the output of the power transmission apparats 100, making it possible to test the performance of the power transmission apparatus 100 under simulated coil switching without running the electric vehicle EV. Because the wireless power transfer system 10 is configured to simulate the energization switching operation of the power transmission coils 110 to thereby test the energization switching operation in a stopped state of the electric vehicle EV, making it possible to test the performance of the power transmission apparatus 100 more readily than when testing it in a moving state of the electric vehicle EV.

The first controller 120 of the power transmission apparatus 100 is configured to switch between the normal mode M1 and the cycle switching mode M2 as the control mode M for controlling the output of the power transmission apparatus 100. This enables the power transmission apparatus 100 to output power in the normal mode M1 during actual usage of the power transmission apparatus 100 and to output power in the cycle switching mode M2 only during testing of the performance of the power transmission apparatus 100. This therefore makes it possible to easily test the actually used power transmission apparatus 100 without the need to rewrite the control procedure into that for use in testing the power transmission apparatus 100.

Additionally, the power reception apparatus 200 is a reference test receiver for testing the power transmission apparatus 100. When the power transmission apparatus 100 is prepared as a plurality of power transmission apparatuses 100, the wireless power transfer system 10 makes it possible to, when testing the power transmission apparatuses 100, easily compare the test results of the power transmission apparatuses 100 with one another.

### Second Embodiment

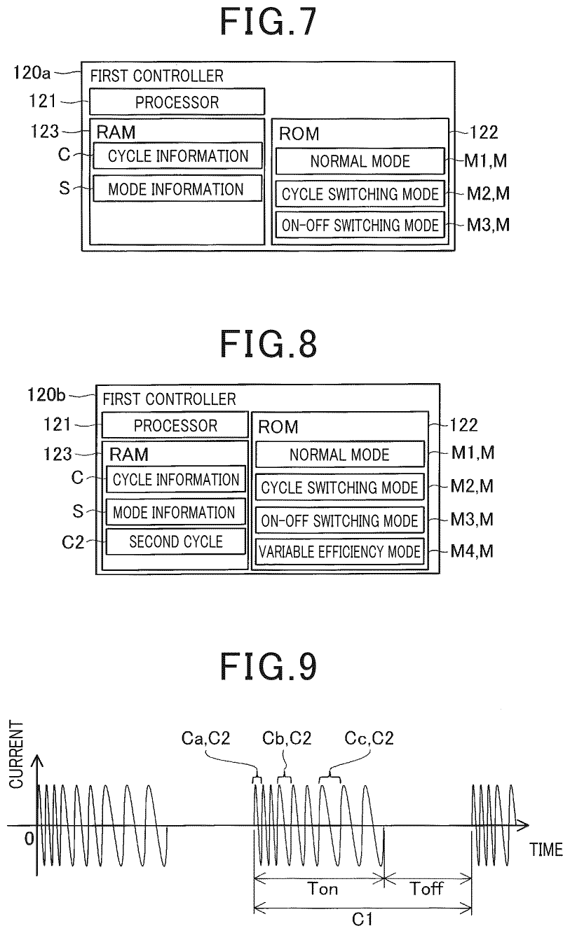

The control modes M of a wireless power transfer system 10a according to the second embodiment additionally include, as illustrated in FIG. 7, an on-off switching mode M3. The output ON period Ton and the output OFF period Toff of each first cycle C1 corresponding to the on-off switching mode M3 are set to be different from one another. A first controller 120a is configured to control the output of the power supply unit 130 with the first cycle C1. The information indicative of the on-off switching mode M3 in addition to the normal mode M1 and the cycle switching mode M2 is stored in the ROM 122 of the first controller 120a. The other configuration of the wireless power transfer system 10a of the second embodiment is identical to that of the wireless power transfer system 10 of the first embodiment.

As described above, the output ON period Ton and the output OFF period Toff of each first cycle C1 corresponding to the on-off switching mode M3 are set to be different from one another. That is, the duty ratio Don of the on-off switching mode M3 is set to be any value, such as a value other than 0.5. The input unit 140 is configured to input, to the first controller 120a, the cycle information C, which includes the output ON period Ton and the output OFF period Toff. That is, the duty ratio Don of the on-off switching mode M3 can be freely set by the input unit 140.

The second embodiment makes it possible to test the performance of the power transmission apparatus 100 in accordance with the variable output ON and OFF periods Ton and Toff corresponding to the actual power-suppliable sections and power-unsuppliable sections.

### Third Embodiment

The control modes M of a wireless power transfer system 10b according to the third embodiment additionally include, as illustrated in FIG. 8, a variable efficiency mode M4. The information indicative of the variable efficiency mode M4 in addition to the normal mode M1, the cycle switching mode M2, and the on-off switching mode M3 is stored in the ROM 122 of the first controller 120a.

Additionally, the input unit 140 of the third embodiment is configured to input, to the first controller 120, information indicative of a second cycle C2. The second cycle C2 denotes a period of the AC power Pi with the power-transfer frequency Fp. Information indicative of the second cycle C2 is stored in the RAM 123. The other configuration of the wireless power transfer system 10b of the third embodiment is identical to that of the wireless power transfer system 10a of the second embodiment.

The variable efficiency mode M4 is a control mode for the power supply unit 130 in which the second cycle C2 of the AC power Pi output from the power supply unit 130 during the output ON period Ton of each first cycle C1 varies. Specifically, the first controller 120 is configured to cause, in the variable efficiency mode M4, the second cycle C2 of the AC power Pi during the output ON period Ton to vary gradually from the start of the output ON period Ton in the variable efficiency mode M4. For example, as illustrated in FIG. 9, the second cycle C2 of the AC power Pi during the output ON period Ton is varied in three stages of a cycle Ca, a cycle Cb, and a cycle Cc. For example, the cycle Ca is set to 11.1 nanoseconds, which corresponds to a frequency of 90 kHz, the cycle Cb is set to 11.8 nanoseconds, which corresponds to 85 kHz, and the cycle Cc is set to 12.7 nanoseconds, which corresponds to 79 kHz.

The information indicative of the second cycle C2 related to the variable efficiency mode M4 is input from the input unit 140 to the first controller 120 based on operations of the input unit 140. In the variable efficiency mode M4, the second cycle C2 is varied such that the varied second cycles C2 are each much shorter than the first cycle C1. For example, if the first cycle C1 is set to 0.036 seconds, the varied second cycles C2 are each much shorter than 0.036 seconds, so that many cycles of the AC power Pi occur within the output ON period Ton.

The third embodiment enables performance testing of the power transmission apparatus 100 while emulating the changes in power-transfer frequency Fp that occur in actual use as the relative position between the vehicle-mounted reception coil 210 and each ground-based transmission coil 110 varies.

### Fourth Embodiment

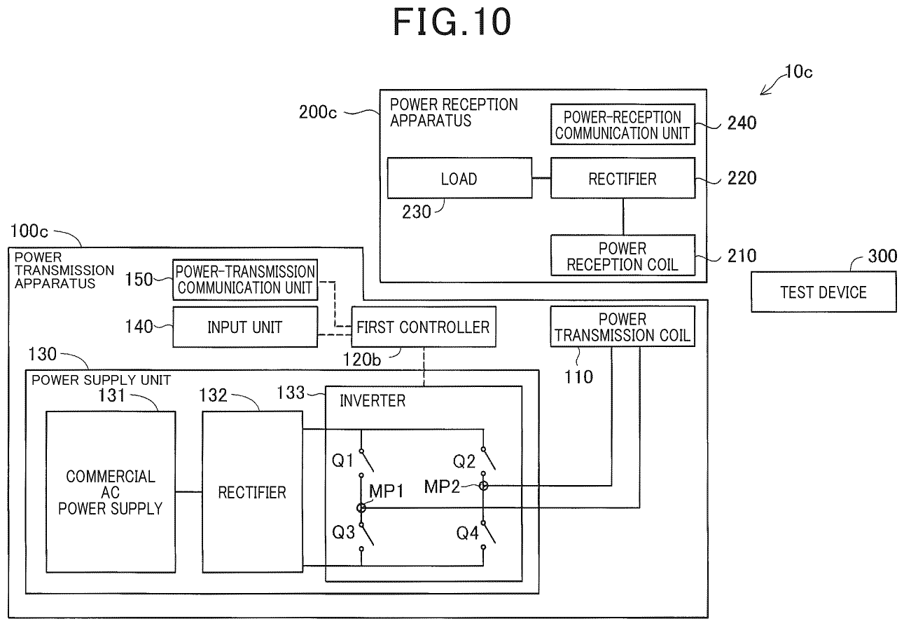

A wireless power transfer system 10c according to the fourth embodiment includes a power transmission apparatus 100c and a power reception apparatus 200c. The power reception apparatus 200c includes, as illustrated in FIG. 10, a power-reception communication unit 240 for transmitting, to the power transmission apparatus 100c, the mode information S for selecting one of the control modes M. Additionally, the power transmission apparatus 100c includes, as illustrated in FIG. 10, a power-transmission communication unit 150 for communicating, with the power-reception communication unit 240, the mode information S. The other configuration of the wireless power transfer system 10c of the fourth embodiment is identical to that of the wireless power transfer system 10b of the third embodiment.

The power-transmission communication unit 150 is configured to communicate with the power-reception communication unit 240 to receive information related to control the inverter 133, such as the mode information S for selecting one of the control modes M, transmitted from the power-reception communication unit 240. For example, the power-transmission communication unit 150 is a hardware module capable of communicating with other devices via Bluetooth®. The power-transmission communication unit 150 is connected to the first controller 120 by one or more communication lines.

The power-reception communication unit 240 is configured to communicate with the power-transmission communication unit 150 of the power transmission apparatus 100c. For example, the power-reception communication unit 240 is a hardware module capable of communicating with other devices via Bluetooth®. The power-reception communication unit 240 includes a second input unit, and the power-reception communication unit 240 is configured to wirelessly communicate with the power-transmission communication unit 150 to accordingly transmit, to the power-transmission communication unit 150, the mode information S for selecting one of the control modes M input from the second input unit.

The wireless power transfer system 10c of the fourth embodiment configured set forth above makes it possible to start test of the power transmission apparatus 100c in response to instructions transmitted from the power reception apparatus 200c. For example, even if the power transmission apparatus 100c is laid on the road, the wireless power transfer system 10c of the fourth embodiment configured set forth above makes it possible to easily test the power transmission apparatus 100c.

### Fifth Embodiment

In a wireless power transfer system 10 according to the fifth embodiment, the power transmission coil 110 and the power reception coil 210 may be arranged at predetermined relative positions such that they do not face each other.

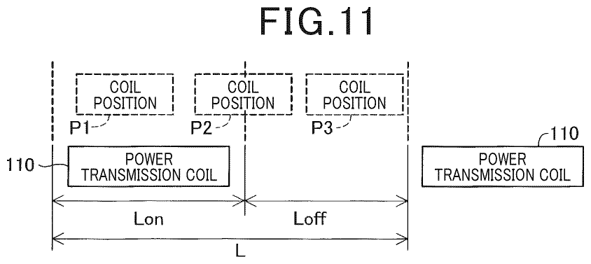

FIG. 11 illustrates position candidates of the power reception coil 210 relative to the power transmission coil 110. Specifically, the position candidates of the power reception coil 210 relative to the power transmission coil 110 include a position P1 within the power-suppliable section Lon of the power transmission coil 110, a position P3 located within the power-unsuppliable section Loff of the power transmission coil 110, and a position P2 disposed to straddle a boundary between the power-suppliable portion Lon and the power-unsuppliable portion Loff.

The wireless power transfer system 10 according to the fifth embodiment is configured to perform the performance test of the power transmission apparatus 100 set forth above when the power reception coil 210 is disposed at a selected one of the positions P1 to P3. Each of the positions P2 and P3 is a position at which the power reception coil 210 does not face the power transmission coil 110. That is, the power transmission coil 110 and the power reception coil 210 of the wireless power transfer system 10 according to the fifth embodiment may be arranged at predetermined related positions such that they do not face each other.

For example, when the power reception apparatus 200 is installed in an electric vehicle EV during actual use of the power transmission apparatus 100, the power reception coil 210 receives power wirelessly from an energized power transmission coil 110 while transitions through the positions P1, P3, and P2 of the energized power transmission coil 110. The electromagnetic coupling state between the power reception coil 210 and the energized power transmission coil 110 are changed at the positions P1, P3, and P2 of the power reception coil 210. That is, power transfer efficiency and EMC between the power reception coil 210 and the energized power transmission coil 110 are changed at the positions P1, P3, and P2 of the power reception coil 210.

The position P2 denotes a position where the power reception coil 210 transitions from the power-suppliable section Lo to the power-unsuppliable section Loff, so that energization switching from the energized power transmission coil 110 to the next power transmission coil 110 is carried out. Arranging the power reception coil 210 at the position P2 enables the relative position of the power reception coil 210 to the power transmission coil 110 to approach a relative position of the power reception coil 210 when energization switching from the energized power transmission coil 110 to the next power transmission coil 110 is carried out during actual use of the power transmission apparatus 100.

The performance of the power transmission apparatus 100 described in the above embodiments is tested each time the power reception coil 210 is located at the corresponding one of the positions P1, P2, and P3. This makes it possible to carry out the performance test of the power transmission apparatus 100 while simulating transition of electromagnetic coupling between the power reception coil 210 and the power transmission coil 110.

Note that determination of the relative position of the power reception coil 210 to the power transmission coil 110 may be carried out in step S150 of the rest procedure illustrated as the flowchart in FIG. 6.

The test method based on the wireless power transfer system 10 according to the fifth embodiment carries out the performance test of the power transmission apparatus 100 while changing the relative position of the power reception coil 210 to the power transmission coil 110. This makes it possible to carry out the performance test of the power transmission apparatus 100 while simulating transition of electromagnetic coupling between the power reception coil 210 and the power transmission coil 110.

For example, when the power reception apparatus 200 is installed in an electric vehicle EV during actual use of the power transmission apparatus 100, the power reception coil 210 receives power wirelessly while energization is sequentially switched among the power transmission coils 110. At that time, because the relative position of the power reception coil 210 to an energized power transmission coil 110 is changed with movement of the electric vehicle EV, electromagnetic coupling between the power reception coil 210 and the energized power transmission coil 110 is changed with movement of the electric vehicle EV.

From this viewpoint, the test method based on the wireless power transfer system 10 according to the fifth embodiment carries out the performance test of the power transmission apparatus 100 while changing, in accordance with change of electromagnetic coupling between the power reception coil 210 and the power transmission coil 110, the relative position of the power reception coil 210 to the power transmission coil 110. This therefore makes it possible to carry out the performance test of the power transmission apparatus 100 while the electromagnetic conditions around the power transmission apparatus 100 are close to those around the actually used power transmission apparatus 100.

Additionally, the test method based on the wireless power transfer system 10 according to the fifth embodiment outputs, from the power supply unit 130, power at a predetermined cycle that matches the energization switching cycle of the power transmission coils 110 during actual use of the power transmission apparatus 100. This therefore makes it possible to perform, with the power reception coil 210 stopped, the performance test of the power transmission apparatus 100 while simulating energization switching of the power transmission coils 110.

### Modifications

The input unit 140 of each embodiment may not include switches for inputting, to the first controller 120, information required to control the power supply unit 130. Specifically, the input unit 140 may have any configuration capable of inputting, to the first controller 120, information required to control the power supply unit 130. For example, the input unit 140 may be configured as a keyboard connected to the first controller 120; operations of the keyboard enable the cycle information C and the mode information S to be input to the first controller 120.

The power reception apparatus 200 according to each embodiment is configured as a reference test receiver for testing the power transmission apparatus 100. However, the power reception apparatus 200 may be configured as a power reception apparatus for receiving power during actual use of the power transmission apparatus 100. For example, in a case of executing the performance test of the power transmission apparatus 100 serving as a charging stand for an electric vehicle EV, the power reception apparatus 200 may be installed in the electric vehicle EV.

The power-suppliable section and the power-unsuppliable section of the power transmission coil 110 may be determined based on electromagnetic coupling between the power transmission coil 110 and the power reception coil 210. However, the power-suppliable section and the power-unsuppliable section of the power transmission coil 110 may be determined based on other means. For example, the power-suppliable section and the power-unsuppliable section of the power transmission coil 110 may be determined based on the outer diameter thereof.

The first controller 120 according to each embodiment includes information indicative of the normal mode M1 and the cycle switching mode M2, but may include information indicative of only the cycle switching mode M2. That is, for test of the power transmission apparatus 100, information indicative of the cycle switching mode M2 may be only stored in the ROM 122 of the first controller 120.

The power supply unit 130 is configured to control its output by controlling the inverter 133 via the first controller 120. However, the power supply unit 130 may be configured to alternatively control the output through another configuration, such as through a linear amplifier.

The power transmission apparatus 100 according to each embodiment includes the input unit 140, but may not include the input unit 140. For example, the first controller 120 may be configured to store the cycle information C without input of the cycle information C from the input unit 140.

The input unit 140 according to each embodiment is configured to input, to the first controller 120, both the cycle information C and the mode information M, but may be configured to input, to the first controller 120, the cycle information without input of the mode information M to the first controller 120.

The cycle information C according to each embodiment includes the first cycle C1, the output ON period Ton, and the output off period Toff, but may include at least part of the first cycle C1, the output ON period Ton, and the output off period Toff or another information related to the first cycle C1, the output ON period Ton, and the output off period Toff. For example, the cycle information C may include the first cycle C1 and the duty ratio Don.

The second cycle C2 is set to be shorter than the first cycle C1 according to at least one of the above embodiments, but the second cycle C2 may be set to be within a predetermined cycle range determined based on the resonant frequency. For example, when the resonant frequency is 85 kHz, the frequency corresponding to the second cycle C2 may be set to be within the range from 79 kHz to 90 KHz inclusive, which includes 85 kHz. That is, the second cycle C2 may be set to be within the range from 11 nanoseconds to 13 nanoseconds inclusive.

In the fourth embodiment, the power-transmission communication unit 150 of the power transmission apparatus 100c and the power-reception communication unit 240 of the power reception apparatus 200c are configured to communicate with one another. However, the power transmission apparatus 100c may not include the power-transmission communication unit 150, and the power reception apparatus 200c may not include the power-reception communication unit 240. For example, the power transmission apparatus 100c and the power reception apparatus 200c may be connected to each other by wire. Specifically, the power reception apparatus 200c may include an input unit configured to input, to the first controller 120, information for controlling the output of the power supply unit 130, which enables the input unit to communicate information with the power transmission apparatus 100c through cable communication.

As illustrated in FIG. 9, the second cycle C2 is varied to gradually increase in three stages from the start of the output ON period Ton in the variable efficiency mode M4 according to at least one of the above embodiments, but the second cycle C2 may be varied to gradually increase in two or more stages in the variable efficiency mode M4. The second cycle C2 may be varied to gradually decrease from the start of the output ON period Ton in the variable efficiency mode M4.

In the fourth embodiment, the power-transmission communication unit 150 and the power-reception communication unit 240 are configured to communicate with one another via Bluetooth®, but may be configured to perform wireless communications using a wireless LAN, such as IrDA®, Zigbee®, or Wi-Fi®.

The first controller 120 according to each embodiment is configured to control the inverter 133 to accordingly control each of the output ON period Ton, the output OFF period Toff, and the first cycle C1, but the first controller 120 may be configured to control other components other than the inverter 133. For example, the power supply unit 130 may include at least one relay between the rectifier 132 and the inverter 133. Specifically, the first controller 120 may be configured to control the at least one relay to accordingly control each of the output ON period Ton, the output OFF period Toff, and the first cycle C1.

The test device 300 according to each embodiment is an apparatus device for performing EMC tests and/or power transfer efficiency between the power transmission apparatus and the power reception apparats, but the test device 300 may be configured as another test device. For example, the test device 300 may be an oscilloscope for checking operations of the power supply unit 130 or a thermography camera for measuring temperature rise of at least one of the components of the wireless power transfer system 10. The test device 300 may be configured to receive current values and/or voltage values measured in the power transmission apparatus 100, 100c or the power reception apparatus 200, 200c and sent therefrom, and use them.

The power transmission apparatus 100, 100c according to each embodiment includes the power transmission coil 110, but may include one or more power transmission coils 110. Similarly, the power reception apparatus 200, 200c according to each embodiment includes the power reception coil 210, but may include one or more power reception coils 210.

The power-reception communication unit 240 according to the fourth embodiment includes a second input unit, and receives the mode information S that is input thereto through operations of the second input unit, but may not include the second input unit. For example, the power-reception communication unit 240 may be configured to store the mode information S, and transmit, to the power-transmission communication unit 150, the mode information S.

The present disclosure is not limited to the above embodiments, and can be implemented by various configurations within the scope of the present disclosure. For example, technical features included in the embodiments, which correspond to technical features included in the exemplary aspects described in the SUMMARY of the present disclosure, can be freely combined with each other or can be freely replaced with another feature in order to solve a part or all of the above issue and/or achieve a part or all of the above advantageous benefits. One or more of the technical features included in the above exemplary embodiments, which are not described as essential elements in the specification, can be omitted as necessity arises.

The following describes features of the present disclosure.

### [First Feature]

A wireless power transfer system (10, 10a, 10b, 10c) according to a first feature includes a power transmission apparatus (100, 100c) whose performance is to be tested by the wireless power transfer system, the power transmission apparatus being configured to wirelessly transmit power (Pi). The wireless power transfer system includes a power reception apparatus (200, 200c) configured to receive the power. The power transmission apparatus includes a power transmission coil (110) for wireless transmission of the power, a power supply unit (130) configured to output, to the power transmission coil, the power to be used for the wireless transmission, and a first controller (120, 120a, 120b, 120c) configured to control the power supply unit. The power reception apparatus comprises a power reception coil (210) for receiving the power transmitted from the power transmission apparatus. The first controller is configured to store information indicative of a plurality of control modes (M) for controlling the output of the power supply. The control modes include a cycle switching mode (M1) in which the first controller changes the output of the power supply unit with a predetermined first cycle (C1).

### [Second Feature]

In the wireless power transfer system according to a second feature, which depends from the first feature, the control modes include a normal mode in which the output of the power supply unit is continuously supplied without being varied in an intermittent cycle.

### [Third Feature]

In the wireless power transfer system according to a third feature, which depends from the second feature, the power transmission apparatus includes an input unit (140) configured to input, when externally operated, information indicative of the first cycle to the first controller.

### [Fourth Feature]

In the wireless power transfer system according to a fourth feature, which depends from the third feature, the first cycle is a cycle defined as a total time of a first period (Ton) during which the output of the power supply unit is executed and a second period (Toff) during which the output of the power supply unit is stopped. The control modes additionally include an on-off switching mode (M3), the first period and the second period of the first cycle corresponding to the on-off switching mode being set to be different from one another. The first controller is configured to control, in the on-off switching mode, the output of the power supply unit based on the information indicative of the first cycle.

### [Fifth Feature]

In the wireless power transfer system according to a fifth feature, which depends from the third feature, the power is AC power having a second cycle (C2) that is shorter than the first cycle. The input unit is configured to input, to the first controller, information indicative of the second cycle. The control modes include a variable efficiency mode (M4) in which the first controller changes the second cycle of the AC power during the first period of the first cycle.

### [Sixth Feature]

In the wireless power transfer system according to a sixth feature, which depends from any one of the second to fifth features, the power reception apparatus includes a power-reception communication unit (240) configured to transmit, to the power transmission apparatus, mode information for selecting one of the control modes. The power transmission apparatus includes a power-transmission communication unit (150) configured to receive the mode information transmitted from the power-reception communication unit (240). The first controller is configured to perform one of the control modes based on the mode information.

### [Seventh Feature]

A test method according to a seventh feature includes
(I) Preparing a power transmission apparatus whose performance is to be tested by the test method, the power transmission apparatus being configured to wirelessly transmit power (Pi),
   the power transmission apparatus including:
      a power transmission coil (110) for wireless transmission of the power, the power transmission coil having a predetermined power-suppliable section of the wireless transmission of the power;
      a power supply unit (130) configured to output, to the power transmission coil, the power to be used for the wireless transmission; and
      a first controller (120) configured to control the power supply unit;
(II) Preparing a power reception apparatus (200, 200c) including a power coil for receiving the power transmitted from the power transmission apparatus;
(III) Preparing a test device for measuring the performance of the power transmission apparatus;
(IV) Arranging the power transmission coil and the power reception coil at predetermined relative positions such that the power reception coil is located within the power-suppliable section of the power transmission coil and does not face the power transmission coil; and
(V) Controlling the power supply unit to output the power from the power supply unit at a predetermined cycle.

### [Eighth Feature]

In the wireless power transfer system according to an eighth feature, which depends from the first feature, the power reception apparatus is a reference test receiver for testing the power transmission apparatus.

### [Ninth Feature]

A power transmission apparatus according to a ninth feature is in a wireless power transfer system for testing a wireless power-transfer performance of the power transmission apparatus. The wireless power transfer system includes a power reception apparatus including a power reception coil so that the power reception apparatus receives, through the power reception coil, power wirelessly transmitted from the power transmission apparatus. The power transmission apparatus includes a power transmission coil for wireless transmission of the power, a power supply unit configured to output, to the power transmission coil, the power to be used for the wireless transmission, and a first controller configured to control the power supply unit. The first controller is configured to store information indicative of a plurality of control modes for controlling the output of the power supply. The control modes include a cycle switching mode in which the first controller changes the output of the power supply unit with a predetermined first cycle.

### [Tenth Feature]

A power reception apparatus according to a tenth feature, including a power receiving coil, is for use with a wireless power transmission apparatus that includes a power transmission coil for wireless transmission of power, a power supply unit configured to output, to the power transmission coil, the power to be used for the wireless transmission, and a first controller configured to control an output of the power supply unit in a plurality of modes including a cycle switching mode in which the transmission output is varied with a predetermined first period. The power reception coil is configured to receive, through the power reception coil, the power wirelessly transmitted from the power transmission apparatus.

1. A wireless power transfer system comprising:
a power transmission apparatus whose performance is to be tested by the wireless power transfer system, the power transmission apparatus being configured to wirelessly transmit power; and
a power reception apparatus configured to receive the power,
wherein:
the power transmission apparatus comprises:
a power transmission coil for wireless transmission of the power;
a power supply unit configured to output, to the power transmission coil, the power to be used for the wireless transmission; and
a first controller configured to control the power supply unit;
the power reception apparatus comprises a power reception coil for receiving the power transmitted from the power transmission apparatus; and
the first controller is configured to store information indicative of a plurality of control modes for controlling the output of the power supply,
the control modes including a cycle switching mode in which the first controller changes the output of the power supply unit with a predetermined first cycle.

2. The wireless power transfer system according to claim 1, wherein:
the control modes include a normal mode in which the output of the power supply unit is continuously supplied without being varied in an intermittent cycle.

3. The wireless power transfer system according to claim 2, wherein:
the power transmission apparatus includes an input unit configured to input, when externally operated, information indicative of the first cycle to the first controller.

4. The wireless power transfer system according to claim 3, wherein:
the first cycle is a cycle defined as a total time of a first period during which the output of the power supply unit is executed and a second period during which the output of the power supply unit is stopped;
the control modes additionally include an on-off switching mode, the first period and the second period of the first cycle corresponding to the on-off switching mode being set to be different from one another; and
the first controller is configured to control, in the on-off switching mode, the output of the power supply unit based on the information indicative of the first cycle.

5. The wireless power transfer system according to claim 4, wherein:
the power is AC power having a second cycle that is shorter than the first cycle;
the input unit is configured to input, to the first controller, information indicative of the second cycle; and
the control modes include a variable efficiency mode in which the first controller changes the second cycle of the AC power during the first period of the first cycle.

6. The wireless power transfer system according to claim 2, wherein:
the power reception apparatus includes a power-reception communication unit configured to transmit, to the power transmission apparatus, mode information for selecting one of the control modes;
the power transmission apparatus includes a power-transmission communication unit configured to receive the mode information transmitted from the power-reception communication unit; and
the first controller is configured to perform one of the control modes based on the mode information.

7. A test method comprising:
preparing a power transmission apparatus whose performance is to be tested by the test method, the power transmission apparatus being configured to wirelessly transmit power,
the power transmission apparatus comprising:
a power transmission coil for wireless transmission of the power, the power transmission coil having a predetermined power-suppliable section of the wireless transmission of the power;
a power supply unit configured to output, to the power transmission coil, the power to be used for the wireless transmission; and
a first controller configured to control the power supply unit;
preparing a power reception apparatus including a power coil for receiving the power transmitted from the power transmission apparatus;
preparing a test device for measuring the performance of the power transmission apparatus;
arranging the power transmission coil and the power reception coil at predetermined relative positions such that the power reception coil is located within the power-suppliable section of the power transmission coil and does not face the power transmission coil; and
controlling the power supply unit to output the power from the power supply unit at a predetermined cycle.

8. The wireless power transfer system according to claim 1, wherein:
the power reception apparatus is a reference test receiver for testing the power transmission apparatus.

9. A power transmission apparatus in a wireless power transfer system for testing a wireless power-transfer performance of the power transmission apparatus, the wireless power transfer system comprising a power reception apparatus including a power reception coil so that the power reception apparatus receives, through the power reception coil, power wirelessly transmitted from the power transmission apparatus, the power transmission apparatus comprising:
a power transmission coil for wireless transmission of the power;
a power supply unit configured to output, to the power transmission coil, the power to be used for the wireless transmission; and
a first controller configured to control the power supply unit,
the first controller being configured to store information indicative of a plurality of control modes for controlling the output of the power supply,
the control modes including a cycle switching mode in which the first controller changes the output of the power supply unit with a predetermined first cycle.

10. A power reception apparatus, comprising a power receiving coil, for use with a wireless power transmission apparatus that includes a power transmission coil for wireless transmission of power, a power supply unit configured to output, to the power transmission coil, the power to be used for the wireless transmission, and a first controller configured to control an output of the power supply unit in a plurality of modes including a cycle switching mode in which the transmission output is varied with a predetermined first period,
the power reception coil being configured to receive, through the power reception coil, the power wirelessly transmitted from the power transmission apparatus.
